(19) United States
(12) Patent Application Publication
(10) Pub. No.: US 2011/0253972 A1
(43) Pub. Date: Oct. 20, 2011

(54) LIGHT-EMITTING DEVICE BASED ON STRAIN-ADJUSTABLE InGaAIN FILM

(75) Inventors: Chuanbing Xiong, Jiangxi (CN); Fengyi Jiang, Jiangxi (CN); Wenqing Fang, Jiangxi (CN); Li Wang, Jiangxi (CN); Guping Wang, Jiangxi (CN)

(73) Assignee: LATTICE POWER (JIANGXI) CORPORATION, Nanchang, Jiangxi (CN)

(21) Appl. No.: 13/059,207

(22) PCT Filed: Aug. 19, 2008
(86) PCT No.: PCT/CN2008/001495

§ 371 Date: Feb. 15, 2011

(51) Int. Cl. H01L 33/06; H01L 33/44

(52) U.S. Cl. 257/13; 438/38; 257/E33.06; 257/E33.008

(57) ABSTRACT

A method for fabricating a semiconductor light-emitting device based on a strain adjustable multilayer semiconductor film is disclosed. The method includes epitaxially growing a multilayer semiconductor film on a growth substrate, wherein the multilayer semiconductor film comprises a first doped semiconductor layer, a second doped semiconductor layer, and a multi-quantum-wells (MQW) active layer; forming an ohmic-contact metal layer on the first doped semiconductor layer; depositing a metal substrate on top of the ohmic-contact metal layer, wherein the density and/or material composition of the metal substrate is adjustable along the vertical direction, thereby causing the strain in the multilayer semiconductor film to be adjustable; etching off the growth substrate; and forming an ohmic-electrode coupled to the second doped semiconductor layer.

### BACKGROUND

1. Field of the Invention

The present invention relates to the fabrication of semiconductor light-emitting devices. More specifically, the present invention relates to a method for fabricating light-emitting devices based on strain-adjustable InGaAlN epitaxial film, which is grown on a Si substrate and later transferred to an corrosion-resistant metal substrate.

2. Related Art

InGaAlN (InₓGa_{y}Al_{1-x-y}N, 0<=x<=1, 0<=y<=1) semiconductor light-emitting devices, especially light-emitting diodes (LED), have been widely used in many applications such as panchromatic large screen displays, traffic lights, backlight sources for display, illuminations, and so on.

Traditionally, InGaAlN materials have been epitaxially grown on a sapphire substrate and are generally made into lateral-electrode LEDs. Such devices often suffer from low efficiency and poor heat-sinking capability. In addition, the p-type conductive layer often absorbs a certain amount of light, which negatively affects the photoelectric properties of the lateral-electrode light-emitting devices. Furthermore, the high cost and the fabrication difficulty of sapphire material have made it difficult to achieve cost-effective large-scale LED production.

Si substrates cost less and are easy to produce. It is economical to grow an InGaAlN epitaxial film on a Si substrate and then fabricate LEDs. However, there are issues associated with a lateral-electrode LED based on InGaAlN film grown on Si substrate, such as low chip-area utilization and absorption of light by the Si substrate and p-side electrode. Although it is possible to attach an electrode on the backside of the Si substrate to make a vertical-electrode LED to increase the chip-area utilization, the light absorption problem remains unsolved. In addition, the existence of an AlN buffer layer in the InGaAlN epitaxial film often results in higher operating voltage for the LED.

It is possible to combine wet-etching and wafer-bonding techniques to transfer an InGaAlN epitaxial film grown on a Si substrate to a new, low-resistance substrate to fabricate a vertical-electrode LED. Such an approach can improve the light-emitting efficiency, increase the chip-area utilization, and lower the serial resistance of the LED. However, the wafer-bonding process often requires high temperature and high pressure. Such a condition often has side effects which can reduce the reliability of the device. In addition, the transferred InGaAlN film often suffers from tensile strain which may also make the device unreliable. The cost of precious metal used in the wafer-bonding process can be another drawback.

### SUMMARY

One embodiment of the present invention provides a method for fabricating a semiconductor light-emitting device based on a strain-adjustable multilayer semiconductor film. The method includes epitaxially growing a multilayer semiconductor film on a growth substrate, wherein the multilayer-semiconductor film comprises a first doped semiconductor layer, a second doped semiconductor layer, and a multi-quantum-wells (MQW) active layer. The method further involves forming an ohmic-contact metal layer on the first doped semiconductor layer and depositing a metal substrate on top of the ohmic-contact metal layer, wherein the density and/or material composition of the metal substrate is adjustable along the vertical direction, thereby causing the strain within the multilayer semiconductor film to be adjustable. In addition, the method involves etching off the growth substrate and forming an ohmic-electrode coupled to the second doped semiconductor layer.

In a variation on this embodiment, the method involves pre-patterning the growth substrate with grooves and mesas.

In a variation on this embodiment, the first doped semiconductor layer is a p-type doped semiconductor layer.

In a variation on this embodiment, the second doped semiconductor layer is an n-type doped semiconductor layer.

In a variation on this embodiment, the metal substrate comprises a single metal.

In a further variation on this embodiment, the method includes adjusting the density of the metal along the vertical direction of the metal substrate in order to adjust the strain direction and level in the multilayer semiconductor film.

In a variation on this embodiment, the metal substrate comprises a metal alloy.

In a further variation on this embodiment, the method includes adjusting the density and weight of metals in the metal alloy along the vertical direction of the metal substrate in order to adjust the strain direction and level in the multilayer semiconductor film.

In a variation on this embodiment, the method includes depositing a passivation layer which covers the sidewalls of the multilayer semiconductor film and/or part of the bottom of the first doped semiconductor layer, and/or part of the top surface of the second doped semiconductor layer.

In a further variation on this embodiment, the passivation layer includes at least one of the following materials: silicon oxide (SiOₓ), silicon nitride (SiNₓ), aluminum oxide (Al₂O₃), and silicon oxynitride (SiOₓN_{y}).

In a variation on this embodiment, the method includes forming an electrode complementary region in the ohmic-contact metal layer, wherein the shape of the electrode complementary region substantially complements the shape of the ohmic electrode.

In a further variation on this embodiment, the electrode complementary region is filled with at least one of the following materials: silicon oxide (SiOₓ), silicon nitride (SiNₓ), aluminum oxide (Al₂O₃), and silicon oxynitride (SiOₓN_{y}).

In a variation on this embodiment, the method includes performing a surface-coarsening treatment on the top surface, which is not covered by the ohmic electrode, of the light-emitting semiconductor device.

### BRIEF DESCRIPTION OF THE FIGURES

FIG. 1A illustrates part of a growth substrate with pre-patterned grooves and mesas in accordance with one embodiment of the present invention.

FIG. 1B illustrates the cross section of the pre-patterned growth substrate in accordance with one embodiment of the present invention.

FIG. 2 illustrates the cross section of a metal-organic-chemical-vapor-deposition (MOCVD) grown InGaAlN film on the pre-patterned substrate in accordance with one embodiment of the present invention.

FIG. 3 presents a diagram illustrating the process of fabricating a vertical-electrode light-emitting device in accordance with one embodiment of the present invention.

FIGS. 4A-4F illustrate the cross section of individual vertical-electrode light-emitting devices in accordance with embodiments of the present invention.

### DETAILED DESCRIPTION

The following description is presented to enable any person skilled in the art to make and use the invention, and is provided in the context of a particular application and its requirements. Various modifications to the disclosed embodiments will be readily apparent to those skilled in the art, and the general principles defined herein may be applied to other embodiments and applications without departing from the spirit and scope of the present invention. Thus, the present invention is not limited to the embodiments shown, but is to be accorded the widest scope consistent with the claims.

### Overview

Embodiments of the present invention provide a light-emitting device based on strain-adjustable InGaAlN film. Transferring an epitaxial InGaAlN film grown on a Si substrate to a metal substrate, which is resistant against corrosive Si etchants, can simplify the fabrication process and lower the fabrication cost. It is also possible to adjust the strain level within the InGaAlN film by adjusting the composition and deposition condition of the metal substrate. Reducing the tensile strain level or reversing it into a compress strain within the InGaAlN film can enhance the reliability of the light-emitting device.

### Epitaxial Growth on Si Substrate

In order to grow a crack-free multilayer InGaAlN film on a conventional large-area substrate (such as a Si wafer) to facilitate the mass production of high-quality, low-cost, short-wavelength LEDs, a growth method that involves pre-patterning the substrate with grooves and mesas is introduced. Pre-patterning the substrate with grooves and mesas can effectively release the stress in the multilayer film that is caused by lattice-constant and thermal-expansion-coefficient mismatches between the substrate surface and the multilayer film.

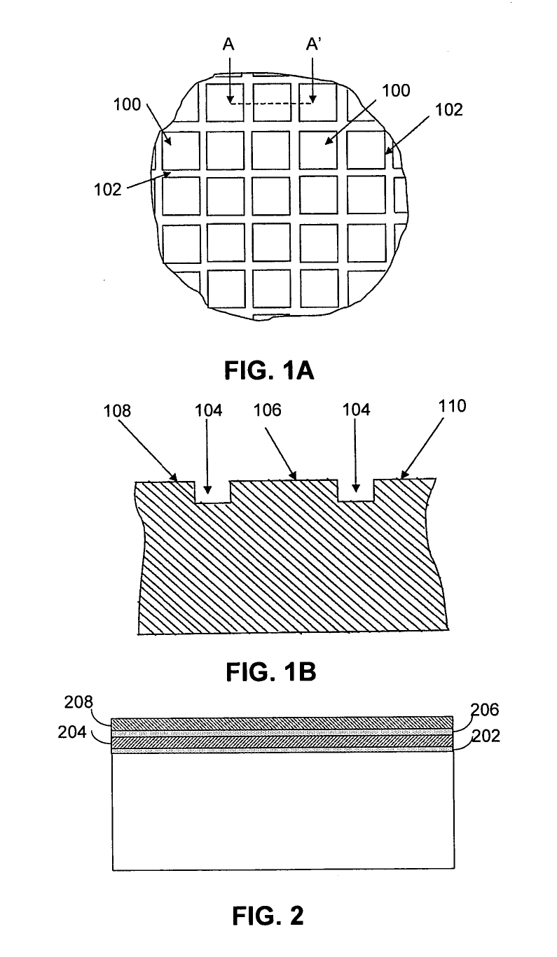

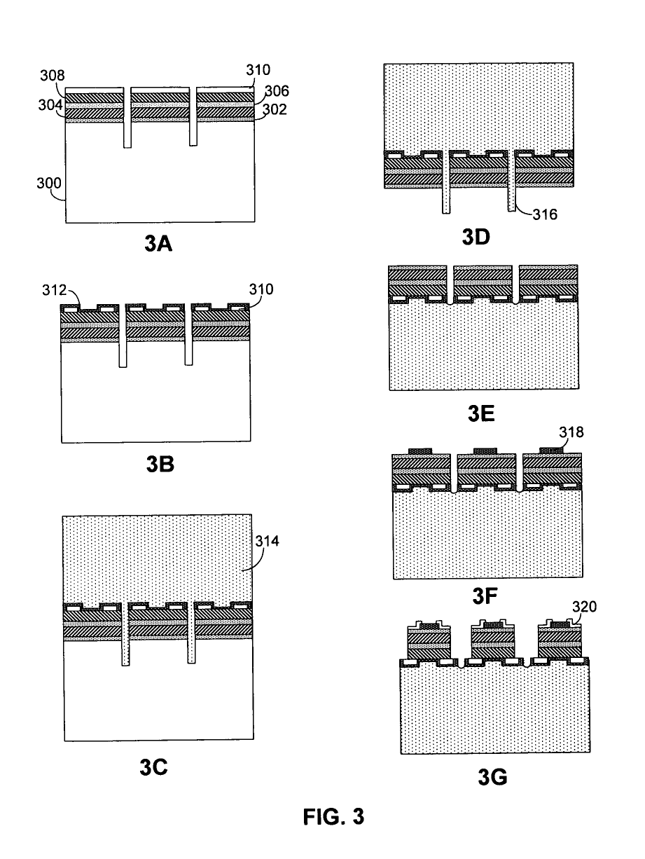

FIG. 1A illustrates a top view of a part of a substrate with a pre-etched pattern using photo lithographic and plasma-etching techniques in accordance with one embodiment of the present invention. Square mesas 100 and grooves 102 are the result of the etching. FIG. 1B more clearly illustrates the structure of mesas and grooves by showing a cross section of the pre-patterned substrate along a horizontal line AA′ in FIG. 1A in accordance with one embodiment of the present invention. As seen in FIG. 1B, the sidewalls of grooves 104 effectively form the sidewalls of the isolated mesa structures, such as mesa 106, and partial mesas 108 and 110. Each mesa defines an independent surface area for growing a respective semiconductor device. The width and the depth of grooves 102 are larger than 3 μm, and the size of mesas 100 is larger than 100 μm².

Note that it is possible to apply different lithographic and etching techniques to form the grooves and mesas on the semiconductor substrate. Also note that other than forming square mesas 100 as shown in FIG. 1A, alternative geometries can be formed by changing the patterns of grooves 102. Some of these alternative geometries can include, but are not limited to: triangular, rectangular, parallelogram, hexagon, circular, or other shapes.

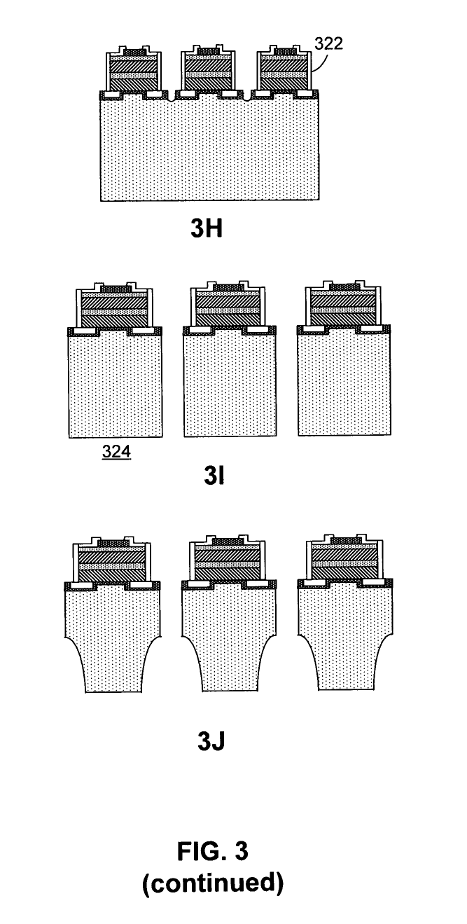

After the preparation of the pre-patterned substrate, an InGaAlN multilayer semiconductor film is grown on the pre-patterned substrate using various growth techniques, which can include but are not limited to metalorganic-chemical-vapor-deposition (MOCVD). FIG. 2 illustrates the cross section of an MOCVD grown InGaAlN multilayer film on the pre-patterned substrate in accordance with one embodiment of the present invention. The multilayer film includes a buffer layer 202, an n-type doped GaN layer 204, an MQW active layer 206, and a p-type GaN layer 208.

In one embodiment, buffer layer 202 can be formed by sequentially growing an Al seed layer, a first AlN buffer layer, a first AlGaN transition layer, a first GaN buffer layer, a second AlGaN transition layer, a second AlN buffer layer, a third AlGaN transition layer, and a second GaN buffer layer. N-type doped layer 204, which can be a Si-doped GaN layer; MQW layer 206; and p-type doped layer 208, which can be a Mg-doped GaN layer, are deposited on buffer layer 202. It is optional to deposit an InGaN tunneling layer (not shown in FIG. 2), which in one embodiment is less than 5 nm thick, on the p-type doped layer. The purpose of depositing such a tunneling layer is to utilize the surface tension exerted onto the GaN layer by the InGaN layer. Such a tension force changes the polarization electric field on the surface of the p-type layer, which in turn increases the surface hole concentration, thus improving the ohmic-contact characteristic. This InGaN layer can also be optionally doped with Mg and can be seen as part of the p-doped layer. It is also optional to grow a layer of Si-doped InGaN inside the n-type doped layer to improve the reverse bias characteristic of the device.

In order to simplify the fabrication process, it is possible to dope a predetermined amount of Si into all buffer layers to make both the AlN buffer layers and the AlGaN transition layers conductive. Consequently, an n-side ohmic-contact electrode can be later directly deposited onto the surface of buffer layer 202; otherwise, buffer layer 202 will need to be partially etched to expose the n-type doped layer.

### Fabrication of Vertical-Electrode LED

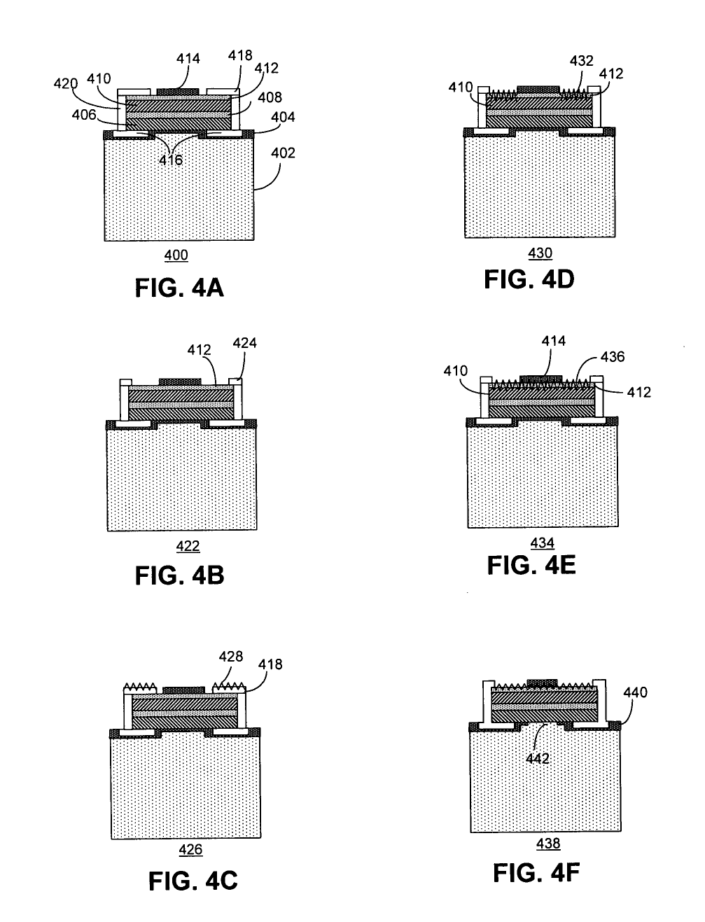

FIG. 3 presents a diagram illustrating the process of fabricating individual vertical-electrode light-emitting devices in accordance with one embodiment of the present invention.

In operation 3A, after growing a buffer layer 302, an n-type doped GaN layer 304, an MQW layer 306, and a p-type doped GaN layer 308 on a pre-patterned substrate 300, a p-side passivation layer 310 is deposited. P-side passivation layer 310 can include one or more of the following materials: SiNₓ, SiOₓ, SiOₓN_{y}, and Al₂O₃. Note that, if p-side passivation layer 310 is formed using SiNₓ or SiOₓ, then during the deposition process, the existence of silane and H₂ carrying gas may passivate the p-type dopant, namely the Mg ions, on the surface of the p-type layer reducing the hole concentration at the p-layer. Therefore, it is optional to perform a thermal annealing process at around 760° C. to activate the Mg ions after the deposition of p-side passivation layer 310.

In operation 3B, a p-side ohmic-contact metal layer 312 is deposited on top of p-side passivation layer 310, which is patterned and partially etched. Because certain metal materials may absorb hydrogen atoms, it is also possible to deposit p-side ohmic-contact metal layer 312 first and then perform the aforementioned thermal annealing, so that the annealing process can both activate Mg ions and form an ohmic contact. In one embodiment of the present invention, after the formation of p-side passivation layer 310, a layer of Pt is evaporation plated to form p-side ohmic-contact metal layer 312, and thermal annealing is performed afterwards. In one embodiment of the present invention, the thermal annealing is performed at around 550° C. for approximately 10 minutes under an atmosphere of N₂:O₂=4:1. The thickness of the Pt p-side ohmic-contact layer can be between 10 Å and 10000 Å. In one embodiment of the present invention, the thickness of the Pt layer is approximately 500 Å. In addition to Pt, choices of materials for p-side ohmic-contact layer 312 include, but are not limited to: Pt/Au alloy; Pt/Rh alloy; NiO/Au; indium-tin-oxide (ITO); alternative layers of Pt and Au; alternative layers of Pt and Rh; alternative layers of Pt, Rh, and gold; Pt/Rh/Au alloy; Pt/Ag alloy; Cu/Ag/Pt alloy; and Ti/Ag/Pt alloy.

In order to increase the light extraction efficiency of the vertical-electrode LED, it is possible to include a transparent layer and an adjacent reflective metal layer in the p-side ohmic-contact layer. The transparent layer can include the aforementioned metal ohmic-contact layer with a thickness of less than 200 Å, or a layer of conductive oxides, such as NiO/Au, ITO, and their combination. The thickness of a conductive oxide layer can be either larger or smaller than 200 Å. The reflective metal layer can be formed by depositing a thin layer of Ag, or Al. It is possible to use a highly reflective alloy to form the reflective metal layer. It is also optional to include a diffusion-barrier layer between the ohmic-contact layer and the reflective layer. The diffusion-barrier layer is highly transparent to light. In addition, the diffusion-barrier layer includes materials with stable physical and chemical properties, thus effectively preventing any destructive effect on the ohmic-contact layer caused by the reflective metal layer. In order to decrease the amount of light absorbed by the p-side ohmic-contact layer, it is possible to form a p-side ohmic-contact layer using a discontinuous matrix of ohmic-contact pads. In such a situation, the p-side ohmic-contact layer only covers a small portion of the p-type doped layer surface, whereas other portions of the p-type doped GaN layer surface are in direct contact with the reflective metal layer or the diffusion-barrier layer. It is also possible to make the diffusion-barrier layer discontinuous. Note that the p-side ohmic-contact metal layer in embodiments of the present invention includes the ohmic-contact layer, the optional diffusion-barrier layer, and the optional reflective layer.

In operation 3C, a metal substrate 314 is deposited on top of the multilayer film. Note that the grooves on pre-patterned substrate 300 are filled in during the deposition of metal substrate 314. Metal substrate 314 can include a single metal, e.g., Cr, or metal alloys, e.g., Cr alloy, all of which are resistant against corrosion of the chemical etchant which is later used to etch off the Si substrate. In one embodiment of the present invention, metal substrate 314 includes a Cr/stainless-steel alloy. Along the vertical direction, metal substrate 314 can have variable material composition and variable densities. Variable material composition and density can lead to variable thermal-expansion coefficient along the vertical direction of metal substrate 314.

Various methods can be used to deposit metal substrate 314, which include, but are not limited to: electric-arc ion plating, magnetron-sputtering deposition, electron-beam (e-beam) evaporation, thermal evaporation, thermal-spray coating, and electroplating. In one embodiment of the present invention, a multi-target electric-arc ion plating equipment is used to deposit metal substrate 314. In one embodiment of the present invention, the multilayer film is first loaded onto a rotational sample stage facing outward, and then Cr and grade-316 stainless-steel targets with a 1:1 ratio are loaded inside the chamber. The chamber is pumped down to a vacuum with a pressure of less than 8×10⁻³ Pa before being filled with Ar gas, and the chamber is then maintained at a pressure of about 0.5 Pa. First, a layer of stainless steel, whose thickness is approximately 100 nm, is plated onto the multilayer film surface. Because the thermal-expansion coefficient of the stainless steel is larger than that of the InGaAlN multilayer film, the stainless steel layer can exert a certain compressive strain upon the InGaAlN multilayer film, thus relaxing the tensile strain within the film. Under certain conditions, it is even possible to reverse the tensile strain to a compressive strain.

Afterwards, Cr and grade-316 stainless steel are simultaneously electroplated on the film surface forming a Cr/stainless-steel alloy layer. Due to the rising temperature in the vacuum chamber during the electroplating process, if the composition and density of metal substrate 314 are constant along the vertical direction, metal substrate 314 will bend once Si substrate 300 is etched away. Because Cr and stainless steel have different thermal-expansion coefficients, and the thermal-expansion coefficient of a material is related to its density, it is possible to adjust the thermal-expansion coefficient along the vertical direction of metal substrate 314 by adjusting its composition and material density. By adjusting the thermal-expansion coefficient of metal substrate 314 along the vertical direction, one can in turn adjust the direction and the intensity of the strain within the InGaAlN multilayer film.

Note that stainless steel has a larger thermal-expansion coefficient than Cr, and the thermal-expansion coefficient of a material is positively correlated with its density, which means the lower the density, the lower the thermal-expansion coefficient. During electroplating, the composition of the deposited alloy can be controlled by adjusting the current level on each target, and the density of the deposited alloy can be controlled by adjusting both the current level and bias voltage on each target. A low-density metal substrate 314 can have a similar thermal-expansion coefficient to that of the GaN material, thus providing increased reliability for the LED. In addition, the InGaAlN multilayer film grown on a Si substrate often experiences tensile strain caused by the substrate, even when it is grown on a pre-patterned Si substrate. The larger the size of the segregated growth mesa, the stronger the tensile strain. To release this tensile strain, metal substrate 314 can have a slightly higher concentration of stainless steel and a slightly higher density. Furthermore, it is also optional for the Cr and stainless steel targets to include a predetermined amount of rare-earth elements in order to increase the thermal conductivity of metal substrate 314.

In operation 3D, Si substrate 300 is etched off using a wet-etching technique. Consequently, the multilayer film is separated from Si substrate 300 and is transferred to metal substrate 314. The chemical etchant used to etch off Si substrate 300 can be a known Si etchant. One embodiment of the present invention etches Si substrate 300 at 80° C. using a mixture of HNO₃, HF, and CH₃COOH at a ratio of 5:2:2. After the removal of Si substrate 300, the metal that fills in the grooves now extends out of the surface of the multilayer film forming metal extensions 316.

In operation 3E, metal extensions 316 are removed by either ultrasonic cleaning or HCl etching.

In operation 3F, n-side ohmic electrodes 318 are formed. Possible materials for forming n-side ohmic electrodes 318 include, but are not limited to: Au/Ge/Ni alloy, Au/Si alloy, TiN, and alloys that include Ti or Al. In one embodiment of the present invention, n-type electrodes 318 are formed using an Au/Ge/Ni alloy which includes 86.24% Au, 11.76% Ge, and 2% Ni. Regardless of the type of metal used in n-type electrodes 318 that is in contact with the n-type doped layer, the top metal layer of n-type electrodes 318 comprises either Ti/Au alloy or Ni/Au alloy, both of which can be conveniently used later for the pressure welding of the electrode lead wire.

In operation 3G, after an n-type passivation layer 320 is deposited on top of the multilayer film covering the buffer layer and part of the n-side ohmic electrode, the edge of each multilayer structure grown on the segregated mesas is removed to ensure an overall higher material quality. The edge removal can be performed using a reactive-ion-etching (RIE) technique and/or a wet-etching technique. The gases used in the RIE can include chlorine or other commonly known GaN etching gases. The chemical solution used in the wet etching can include H₃PO₄, NaOH, and KOH. Ultraviolet radiation can also be included in the wet-etching process. The masking material for the selective etching can include photoresist, and/or metal, and/or passivation materials. Materials used to form passivation layer 320 can be the same or different from the ones used to form passivation layer 310.

In operation 3H, a sidewall-passivation layer 322 is deposited on the sidewalls of each multilayer structure. Materials used to form sidewall-passivation layer 322 can be the same or different from those used to form passivation layer 310.

In operation 3I, individual LED devices, such as LED 324, are formed by dividing the multilayer film and metal substrate. Techniques which can be used to divide the metal substrate include, but are not limited to the following: laser dicing, mechanical dicing, mechanical cleaving, and chemical etching. It is also possible to use a combination of chemical etching and dicing techniques. Illustration 3J shows the cross section of individual LEDs separated by combining a chemical-etching technique and a dicing technique.

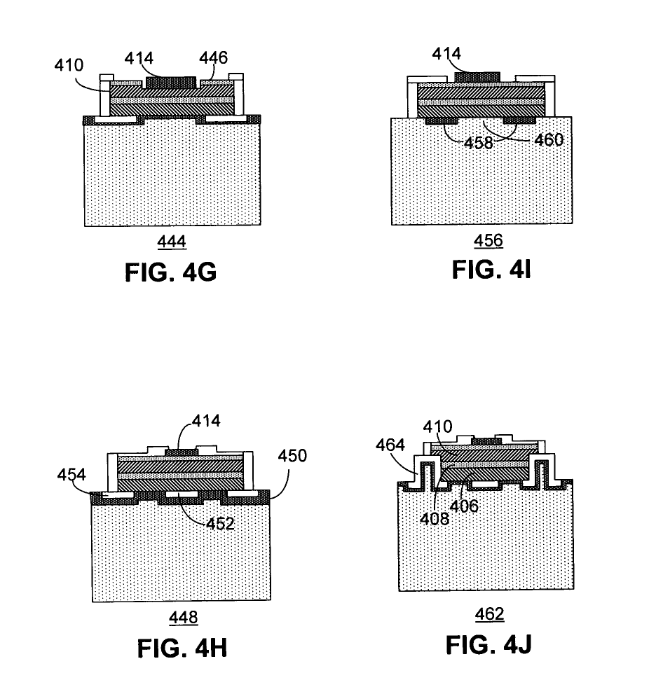

FIG. 4A illustrates the cross section of an individual LED 400 in accordance with one embodiment of the present invention. LED 400 includes a non-silicon substrate 402, a p-side ohmic contact metal layer 404, a p-type doped layer 406, an active layer 408, an n-type doped layer 410, a buffer layer 412, an n-side ohmic electrode 414, a p-type passivation layer 416, an n-type passivation layer 418, and a sidewall passivation layer 420. The structure of LED 400 and its fabrication process are similar to those of LED 324 illustrated in FIG. 3, except that in LED 400, n-type passivation layer 418 only covers buffer layer 412 and does not cover part of n-side ohmic electrode 414.

FIG. 4B illustrates the cross section of an individual LED 422 in accordance with one embodiment of the present invention. The structure of LED 422 and its fabrication process are similar to those of LED 400 illustrated in FIG. 4A, except that in LED 422, n-type passivation layer 424 only covers the edge of buffer layer 412 leaving most of the light-emitting surface of LED 422 uncovered.

FIG. 4C illustrates the cross section of an individual LED 426 in accordance with one embodiment of the present invention. The structure of LED 426 and its fabrication process are similar to those of LED 400 illustrated in FIG. 4A, except that in LED 426, n-type passivation layer 418 undergoes a surface-coarsening treatment, during which surface-coarsening patterns 428 are formed on the surface of n-type passivation layer 418. The surface-coarsening patterns include, but are not limited to: hexagonal-pyramid, cylinder, cone, ring, and other shapes. Surface-coarsening patterns 428 can be formed using at least one of the following processes: photoelectric chemical etching, chemical etching, ICP etching, and RIE etching.

FIG. 4D illustrates the cross section of an individual LED 430 in accordance with one embodiment of the present invention. The structure of LED 430 and its fabrication process are similar to those of LED 422 illustrated in FIG. 4B, except that in LED 430, buffer layer 412 and n-type doped layer 410 undergo a surface-coarsening treatment, during which surface-coarsening patterns 432 are formed on the top surface of buffer layer 412. The surface-coarsening patterns include, but are not limited to: hexagonal-pyramid, cylinder, cone, ring, and other irregular shapes. The surface-coarsening patterns can be formed using at least one of the following processes: photoelectric chemical etching, chemical etching, ICP etching, and RIE etching. The penetration depth of surface-coarsening patterns 432 is less than ⅔ of the thickness of n-type doped layer 410.

FIG. 4E illustrates the cross section of an individual LED 434 in accordance with one embodiment of the present invention. The structure of LED 434 and its fabrication process are similar to those of LED 430 illustrated in FIG. 4D, except that in LED 434, n-side ohmic electrode 414 is formed after buffer layer 412 and n-type doped layer 410 undergo a surface-coarsening treatment, during which surface-coarsening patterns 436 are formed on the top surface of buffer layer 412, covering the entire top surface of buffer layer 412.

FIG. 4F illustrates the cross section of an individual LED 438 in accordance with one embodiment of the present invention. The structure of LED 438 and its fabrication process are similar to those of LED 434 illustrated in FIG. 4E, except that in LED 438, p-side ohmic electrode 440 includes an electrode complementary region 442, which is formed by removing part of the metal contact in p-side ohmic electrode 404. As a result, n-side ohmic electrode 414 and p-side ohmic electrode 440 are substantially complementary to each other. Using complementary vertical electrodes can increase the light-extracting efficiency because the majority of carrier recombination now occurs at the active-layer regions where upward light propagation is not obstructed by the upper electrode.

FIG. 4G illustrates the cross section of an individual LED 444 in accordance with one embodiment of the present invention. The structure of LED 444 and its fabrication process are similar to those of LED 422 illustrated in FIG. 4B, except that in LED 444, n-type electrode 414 is formed after buffer layer 446 is partially etched, and as a result, n-type electrode 414 is in direct contact with n-type doped layer 410.

FIG. 4H illustrates the cross section of an individual LED 448 in accordance with one embodiment of the present invention. The structure of LED 448 and its fabrication process are similar to those of LED 324 illustrated in FIG. 3, except that in LED 448, p-side ohmic electrode 450 includes an electrode complementary region 452 corresponding to the shape of n-side ohmic electrode 414. Note that electrode complementary region 452 is filled with similar materials that form p-type passivation layer 454.

FIG. 4I illustrates the cross section of an individual LED 456 in accordance with one embodiment of the present invention. The structure of LED 456 and its fabrication process are similar to those of LED 422 illustrated in FIG. 4B, except that LED 456 does not include a p-type passivation layer, and p-side ohmic electrode 458 and n-type electrode 414 are substantially complementary to each other. Region 460 is an electrode complementary region.

FIG. 4J illustrates the cross section of an individual LED 462 in accordance with one embodiment of the present invention. The structure of LED 462 and its fabrication process are similar to those of LED 448 illustrated in FIG. 4H, except that in LED 462, p-type passivation layer 464 is formed on an etched cross section of the p-n junction, covering the etched sidewall of p-type doped layer 406, active layer 408, and n-type doped layer 410.

The foregoing descriptions of embodiments of the present invention have been presented only for purposes of illustration and description. They are not intended to be exhaustive or to limit the present invention to the forms disclosed. Accordingly, many modifications and variations will be apparent to practitioners skilled in the art. Additionally, the above disclosure is not intended to limit the present invention. The scope of the present invention is defined by the appended claims.

What is claimed is:

1. A method for fabricating a semiconductor light-emitting device based on a strain-adjustable multilayer semiconductor film, the method comprising:
epitaxially growing a multilayer semiconductor film on a growth substrate, wherein the multilayer-semiconductor film comprises a first doped semiconductor layer, a second doped semiconductor layer, and a multi-quantum-wells (MQW) active layer;
forming an ohmic-contact metal layer on the first doped semiconductor layer;
depositing a metal substrate on top of the ohmic-contact metal layer, wherein the density and/or material composition of the metal substrate is adjustable along the vertical direction, thereby causing the strain in the multilayer semiconductor film to be adjustable;
etching off the growth substrate; and
forming an ohmic-electrode coupled to the second doped semiconductor layer.

2. The method of claim 1, further comprising:
pre-patterning the growth substrate with grooves and mesas.

3. The method of claim 1,
wherein the first doped semiconductor layer is a p-type doped semiconductor layer.

4. The method of claim 1,
wherein the second doped semiconductor layer is an n-type doped semiconductor layer.

5. The method of claim 1,
wherein the metal substrate comprises a single metal.

6. The method of claim 5, further comprising adjusting the density of the metal along the vertical direction of the metal substrate in order to adjust the strain direction and level in the multilayer semiconductor film.

7. The method of claim 1,
wherein the metal substrate comprises a metal alloy.

8. The method of claim 7, further comprising adjusting the density and weight of metals in the metal alloy along the vertical direction of the metal substrate in order to adjust the strain direction and level in the multilayer semiconductor film.

9. The method of claim 1, further comprising depositing a passivation layer which covers the sidewalls of the multilayer-semiconductor film, and/or part of the bottom surface of the first doped semiconductor layer, and/or part of the top surface of the second doped semiconductor layer.

10. The method of claim 9,
wherein the passivation layer comprises at least one of:
silicon oxide (SiOₓ),
silicon nitride (SiN_{x,}),
aluminum oxide (Al₂O₃), and
silicon oxynitride (SiOₓN_{y}).

11. The method of claim 1, further comprising forming an electrode complementary region in the ohmic-contact metal layer, wherein the shape of the electrode complementary region substantially complements the shape of the ohmic electrode.

12. The method of claim 11, wherein the electrode complementary region is filled with at least one of the following materials:
silicon oxide (SiOₓ),
silicon nitride (SiN_{x,}),
aluminum oxide (Al₂O₃), and
silicon oxynitride (SiOₓN_{y}).

13. The method of claim 1, further comprising performing a surface-coarsening treatment on part of the top surface, which is not covered by the ohmic electrode, of the light-emitting semiconductor device.

14. A semiconductor light-emitting device based on a strain-adjustable multilayer-semiconductor film, the device comprising:
a metal substrate, wherein the density and/or material composition of the metal substrate along the vertical direction are adjustable;
a multilayer semiconductor film situated above the metal substrate, wherein the multilayer-semiconductor film comprises a first doped semiconductor layer, a second doped semiconductor layer, and a multi-quantum-wells (MQW) active layer;
an ohmic-contact metal layer situated between the first doped semiconductor layer and the metal substrate; and
an ohmic electrode coupled to the second doped semiconductor layer.

15. The light-emitting device of claim 14,
wherein the first doped semiconductor layer is a p-type doped semiconductor layer.

16. The light-emitting device of claim 14,
wherein the second doped semiconductor layer is an n-type doped semiconductor layer.

17. The light-emitting device of claim 14, wherein the metal substrate comprises a single metal.

18. The light-emitting device of claim 17,
wherein the density of the metal along the vertical direction of the metal substrate is adjustable.

19. The light-emitting device of claim 14, wherein the metal substrate comprises a metal alloy.

20. The light-emitting device of claim 19,
where in the density and weight of metals in the metal alloy along the vertical direction of the metal substrate are adjustable.

21. The light-emitting device of claim 14, further comprising a passivation layer which covers the sidewalls of the multilayer-semiconductor film, and/or part of the bottom surface of the first doped semiconductor layer, and/or part of the top surface of the second doped semiconductor layer.

22. The light-emitting device of claim 21,
wherein the passivation layer comprises at least one of:
silicon oxide (SiOₓ),
silicon nitride (SiN_{x,}),
aluminum oxide (Al₂O₃), and
silicon oxynitride (SiOₓN_{y}).

23. The light-emitting device of claim 14, further comprising an electrode complementary region in the ohmic-contact metal layer, wherein the shape of the electrode complementary region substantially complements the shape of the ohmic electrode.

24. The light-emitting device of claim 23, wherein the electrode complementary region is filled with at least one of the following materials:
silicon oxide (SiOₓ),
silicon nitride (SiN_{x,}),
aluminum oxide (Al₂O₃), and
silicon oxynitride (SiOₓN_{y}).

25. The light-emitting device of claim 14,
wherein part of the top surface, which is not covered by the ohmic electrode, of the light-emitting semiconductor device undergoes a surface-coarsening treatment.
